(19) United States
(12) Patent Application Publication
(10) Pub. No.: US 2025/0007505 A1
(43) Pub. Date: Jan. 2, 2025

(54) PULSE FREQUENCY MODULATION (PFM) MODE FOR A MULTIPHASE CONVERTER

(71) Applicant: TEXAS INSTRUMENTS INCORPORATED, DALLAS, TX (US)

(72) Inventors: Janne PAHKALA, OULU (FI); Ari VAANANEN, OULU (FI)

(21) Appl. No.: 18/678,694

(22) Filed: May 30, 2024

Related U.S. Application Data
(60) Provisional application No. 63/523,689, filed on Jun. 28, 2023.

(51) Int. Cl. H03K 7/06; H02M 1/00; H03K 3/037

(52) U.S. Cl. CPC H03K 7/06; H02M 1/0009; H03K 3/037

(57) ABSTRACT

A circuit includes a plurality of control logic circuits, each of the control logic circuits configured to provide respective pulses at different time periods. The circuit further includes a timer circuit configured to provide a timer signal to each of the control logic circuits based on an output voltage, wherein the timer signal determines a frequency of the respective pulses. Furthermore, the circuit includes a rotator circuit configured to provide a plurality of rotator signals to the control logic circuits, respectively, wherein each control logic circuit is configured to determine a time period of the different time periods during which to generate the respective pulses based on the respective rotator signal.

### CROSS-REFERENCE TO RELATED APPLICATION

This application claims priority to U.S. provisional patent application No. 63/523,689, filed Jun. 28, 2023, which application is hereby incorporated herein by reference in its entirety.

### TECHNICAL FIELD

This description relates to current mode multiphase power converters, in particular, to a system that facilitates a rotation pulse frequency modulation (PFM) mode in current mode multiphase power converters.

### BACKGROUND

Power converters are a family of electrical circuits which convert electrical energy from one level of voltage/current/frequency to another using semiconductor-based electronic switches. A characteristic of these types of circuits is that the switches are operated only in one of two states either fully ON or fully OFF-unlike other types of electrical circuits where the control elements are operated in a (near) linear active region. Multiphase power converters include a parallel set of power electronic stages or phases, each stage having corresponding switch components. Each of the power electronic stages or phases are coupled to a common output terminal. Multiphase operation gives flexibility for powering various loads as the phases can be configured to operate in parallel or as stand-along configuration. Further, the multiphase power converters provide scalable output current and reduces output current ripple.

Multiphase power converters are operated in both pulse width modulation (PWM) mode and pulse frequency modulation (PFM) mode. In some examples, the multiphase power converters transition from the PWM mode to the PFM mode during light load conditions. Multiphase power converters, which are used to power automotive processors, are required to operate with minimized output capacitance due to cost sensitive market. The multiphase power converters are also required to have a low power mode with good efficiency to ensure battery life.

### SUMMARY

An example circuit includes a plurality of control logic circuits, each of the control logic circuits configured to provide respective pulses at different time periods. The circuit further includes a timer circuit configured to provide a timer signal to each of the control logic circuits based on an output voltage, wherein the timer signal determines a frequency of the respective pulses. Furthermore, the circuit includes a rotator circuit configured to provide a plurality of rotator signals to the control logic circuits, respectively, wherein each control logic circuit is configured to determine a time period of the different time periods during which to generate the respective pulses based on the respective rotator signal.

Another example circuit includes a first control logic circuit having a first input, a second input, and an output; and a second control logic circuit having a first input, a second input, and an output. The circuit further includes a timer circuit having an input and an output, the output coupled to the first input of the first control logic circuit and to the first input of the second control logic circuit, and the input of the timer circuit adapted to be coupled to a common output terminal. Furthermore, the circuit includes a rotator circuit having an input, a first output and a second output, the input coupled to the output of the timer circuit, the first output coupled to the second input of the first control logic circuit and the second output coupled to the second input of the second control logic circuit.

A yet another example includes a system that includes a plurality of converter circuits, wherein an output terminal of each of the converter circuits is coupled to a common output terminal; and a plurality of control logic circuits each configured to provide respective pulse frequency modulation (PFM) pulses to a respective one of the converter circuits at different time periods. The system further includes a pulse frequency modulation (PFM) timer circuit configured to provide a timer signal to each respective one of the control logic circuits, the timer signal being based on an amplitude of an output voltage at the common output terminal of the converter circuits, wherein the timer signal determines a frequency of the respective pulses. Furthermore, the system includes a rotator circuit configured to provide one of a plurality of rotator signals to each respective one of the control logic circuits, wherein each of the rotator signals determines a time period of the different time periods during which the corresponding control logic circuit generates the respective pulses.

### BRIEF DESCRIPTION OF THE DRAWINGS

FIG. 1 illustrates a simplified block diagram of an example multiphase power converter system.

FIG. 2 illustrates an example implementation of a multiphase power converter system.

FIG. 3 illustrates an example implementation of a PFM timer circuit.

FIG. 4 illustrates an example implementation of a control logic circuit.

FIG. 5 illustrates another example implementation of a control logic circuit.

FIG. 6 illustrates a graph that depicts various plots associated with a multiphase power converter system during a pulse frequency modulation (PFM) mode of operation.

### DETAILED DESCRIPTION

This description relates to circuits and systems that facilitates a rotation pulse frequency modulation (PFM) mode in current mode multiphase power converters. In particular, the description relates to a multiphase power converter system that can operate in a pulse width modulation (PWM) mode and a PFM mode (e.g., the rotation PFM mode). The multiphase power converter system includes a plurality of power converter circuits, an output terminal of each of the power converter circuits being coupled to a common output terminal. The multiphase power converter system further includes a plurality of control logic circuits each configured to provide respective pulse frequency modulation (PFM) pulses to a respective one of the power converter circuits at different time periods. Furthermore, the multiphase power converter system includes a pulse frequency modulation (PFM) timer circuit configured to provide a PFM timer signal to each of the control logic circuits, the PFM timer signal being based on an amplitude of an output voltage at the common output terminal of the power converter circuits. The PFM timer signal determines a frequency of the respective PFM pulses. In addition, the multiphase power converter system includes a PFM rotator circuit configured to provide a plurality of PFM rotator signals to the plurality of control logic circuits, respectively. In some examples, each of the PFM rotator signals determines a time period of the different time periods during which the corresponding control logic circuit generates the respective PFM pulses.

The multiphase power converter system further includes a plurality of current sense comparator circuits respectively coupled to the plurality of the control logic circuits. Each of the control logic circuits is configured to generate the respective PFM pulses based on control signal(s) provided by the respective current comparator circuit. Each of the control logic circuits is configured to generate the respective PFM pulses during the PFM mode of the multiphase power converter system. During the PFM mode, each of the current sense comparator circuits is enabled only during the time period when the respective control logic circuit is providing the PFM pulses. In some examples, each of the control logic circuits is further configured to generate respective PWM pulses (to be provided to the respective power converter circuit) based on control signal(s) provided by the respective current comparator circuit during the PWM mode.

In some examples, providing the PFM pulses in different time periods by the plurality of control logic circuits enables to reduce the output voltage ripple of the multiphase power converter system even while using a small output capacitance. Further, selectively enabling the current sense comparator circuits only when the corresponding control logic circuit is providing the respective PFM pulses enables to reduce the power consumption of the multiphase power converter system, thereby ensuring extended battery life. Further, reusing the current sense comparator circuits for generating both the PFM pulses and the PWM pulses enables to achieve small silicon size and a lower cost solution.

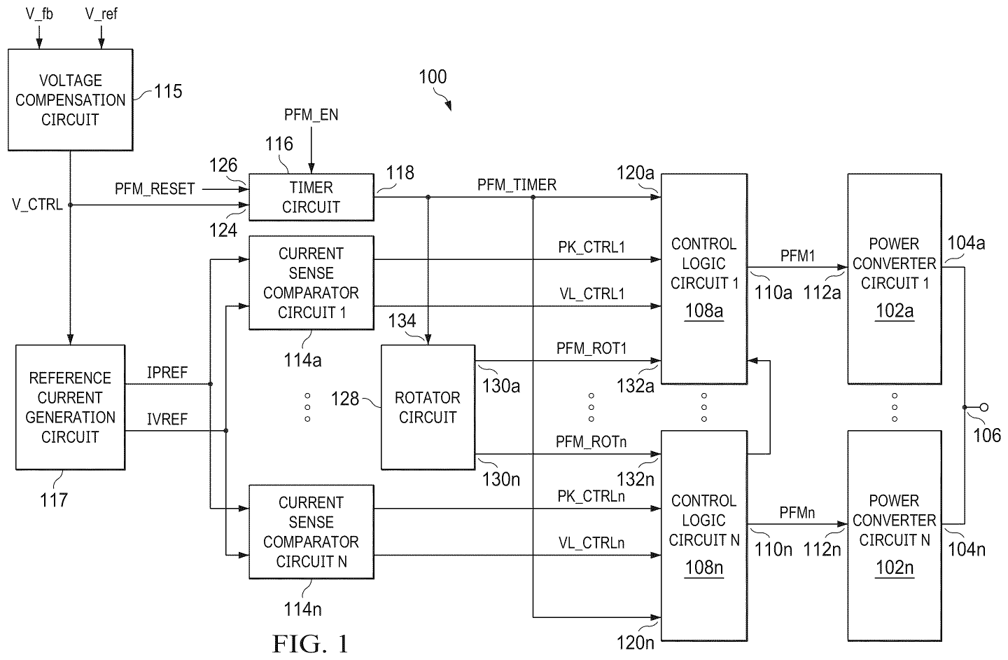

FIG. 1 illustrates a simplified block diagram of an example multiphase power converter system 100. The multiphase power converter system 100 may be implemented as part of a variety of automotive and industrial applications including surround view systems, driver monitoring system, machine vision, industrial robots, medical imaging, surveillance cameras etc. The multiphase power converter system 100 may be implemented using one or more integrated circuits (ICs). The multiphase power converter system 100 includes a plurality of power converter circuits 102a-102n, output terminals 104a-104n of each of the power converter circuits 102a-102n being coupled to a common output terminal 106. In some examples, the plurality of power converter circuits 102a-102n may include a plurality of buck converter circuits. However, in other examples, the plurality of buck converter circuits 102a-102n may include a plurality of boost converter circuits, a plurality of buck-boost converter circuits etc.

The multiphase power converter system 100 further includes a plurality of control logic circuits 108a-108n respectively coupled to the plurality of power converter circuits 102a-102n. In particular, pulse output terminals 110a-110n of the control logic circuits 108a-108n are coupled respectively to pulse input terminals 112a-112n of the power converter circuits 102a-102n. In some examples, the multiphase power converter system 100 is configured to operate both in pulse width modulation (PWM) mode and PFM mode (e.g., a rotation PFM mode). Alternately, in other examples, the multiphase power converter system 100 may be configured to operate only in PFM mode. During the PWM mode, each of the control logic circuits 108a-108n is configured to provide respective PWM pulses (not shown) via the pulse output terminals 110a-110n to a respective one of the pulse input terminals 112a-112n of the power converter circuits 102a-102n at different time periods.

In this example, the multiphase power converter system 100 is shown to operate in the PFM mode. During the PFM mode, each of the control logic circuits 108a-108n is configured to provide respective pulses (also referred to as pulse frequency modulation (PFM) pulses) PFM1-PFMn via the pulse output terminals 110a-110n to a respective one of the pulse input terminals 112a-112n of the power converter circuits 102a-102n at different time periods. For example, the control logic circuit 108a is configured to provide the respective PFM pulse PFM1 to the power converter circuit 102a during a first time period and the control logic circuit 108n is configured to provide the respective PFM pulse PFMn to the power converter circuit 102n during a second different time period. The multiphase power converter system 100 is configured such that at any time period during the PFM mode, one of the control logic circuits 108a-108n is providing the respective PFM pulses. The multiphase power converter system 100 further includes a plurality of current sense comparator circuits 114a-114n respectively coupled to the control logic circuits 108a-108n that facilitates each of the control logic circuits 108a-108n to generate the respective PWM pulses during the PWM mode and the respective PFM pulses during the PFM mode.

Each of the current sense comparator circuits 114a-114n is configured to provide a respective peak current control signal (e.g., PK_CTRL1-PK_CTRLn) and a respective valley current control signal (e.g., VL_CTRL1-VL_CTRLn) to a respective control logic circuit to enable the control logic circuit to generate the respective PFM pulses or the PWM pulses. In some examples, each of the current sense comparator circuits 114a-114n is configured to provide the respective peak current control signal based on a peak reference current I_{PREF}. Further, each of the current sense comparator circuits 114a-114n is configured to provide the respective valley current control signal based on a valley reference current I_{VREF}. The multiphase power converter system 100 further includes a voltage compensation circuit 115 configured to compare a feedback voltage v_fb indicative of an output voltage at the common output terminal 106 and an output reference voltage v_ref to generate a voltage control signal V_CTRL at an output of the voltage compensation circuit 115. Furthermore, the multiphase power converter system 100 includes a reference current generation circuit 117 configured to generate the peak reference current I_{PREF} and the valley reference current I_{VREF} based on the voltage control signal V_CTRL.

The multiphase power converter system 100 further includes a timer circuit 116 (also referred to as a PFM timer circuit 116) having a PFM timer output terminal 118 that is coupled to PFM input terminals 120a-120n of the control logic circuits 108a-108n. The PFM timer circuit 116 is configured to provide a timer signal (also referred to as a PFM timer signal) PFM_TIMER via the PFM timer output terminal 118 to the PFM input terminals 120a-120n of the control logic circuits 108a-108n. The PFM timer circuit 116 further includes a reset terminal 126 and a control voltage input terminal 124 that is coupled to the common output terminal 106 via the voltage compensation circuit 115. The PFM timer signal PFM_TIMER is generated based on an amplitude of an output voltage at the common output terminal 106 (in particular, based on the V_CTRL that is in turn derived based on the amplitude of the output voltage at the common output terminal 106) and a reset signal (also referred to as a PFM reset signal) PFM_RESET at the reset terminal 126. In some examples, the PFM timer signal PFM_TIMER determines a frequency of the respective PFM pulses PFM1-PFMn. In some examples, the multiphase power converter system 100 further includes a reset signal generation circuit (also referred to as a PFM reset signal generation circuit) (not shown) that provides/generates the PFM reset signal PFM_RESET. In some examples, the PFM timer circuit 116 is configured to be enabled and disabled based on a PFM enable signal PFM_EN. In particular, enabling the PFM timer circuit 116 facilitates the multiphase power converter system to operate in the PFM mode and disabling the PFM timer circuit 116 facilitates the multiphase power converter system 100 to operate in the PWM mode. In some examples, the PFM enable signal PFM_EN has a first value to enable the PFM timer circuit 116 during the PFM mode and the PFM enable signal PFM_EN has a second value to disable the PFM timer circuit 116 during the PWM mode.

In addition, the multiphase power converter system 100 includes a rotator circuit 128 (also referred to as a PFM rotator circuit 128) having a plurality of PFM rotator output terminals 130a-130n coupled respectively to the rotator input terminals 132a-132n of the control logic circuits 108a-108n. The PFM rotator circuit 128 further includes a PFM rotator input terminal 134 that is coupled to the PFM timer output terminal 118. The PFM rotator circuit 128 is configured to generate/provide a plurality of rotator signals (also referred to as PFM rotator signals) PFM_ROT1-PFM_ROTn via the plurality of PFM rotator output terminals 130a-130n, respectively, to the rotator input terminals 132a-132n of the control logic circuits 108a-108n. Each of the PFM rotator signals PFM_ROT1-PFM_ROTn determines a time period of the different time periods during which the corresponding control logic circuits 108a-108n starts to generate the respective PFM pulses PFM1-PFMn. For example, the control logic circuits 108a-108n are configured to start generating the respective PFM pulses PFM1-PFMn only during the time periods when the respective PFM rotator signal is active. In some examples, the PFM rotator circuit 128 is configured to generate the plurality of PFM rotator signals PFM_ROT1-PFM_ROTn based on the PFM timer signal PFM_TIMER at the PFM rotator input terminal 134.

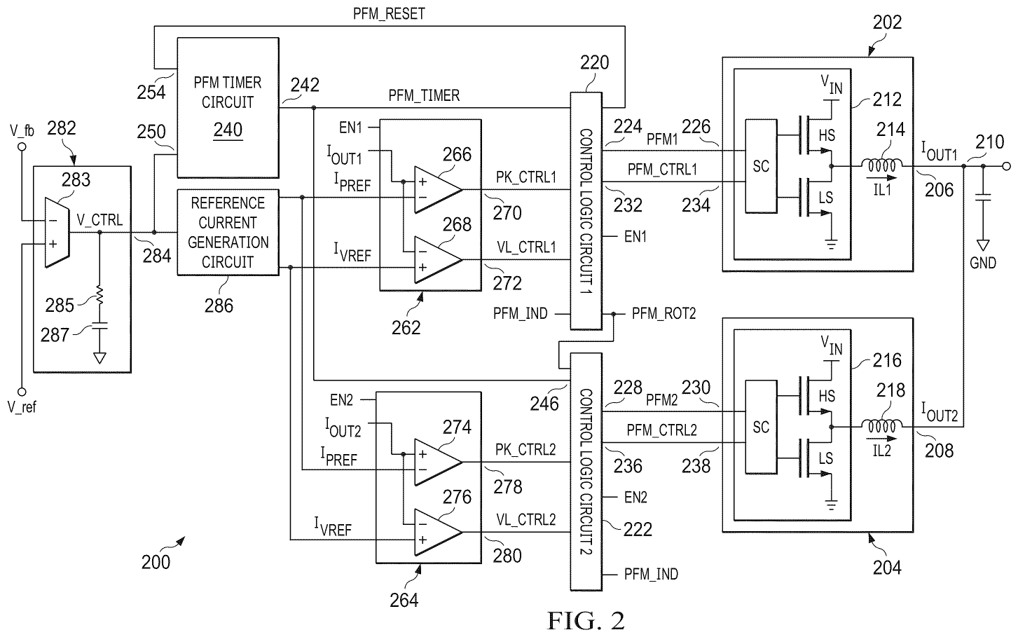

FIG. 2 illustrates an example implementation of a multiphase power converter system 200. The multiphase power converter system 200 depicts one possible way of implementation of the multiphase power converter system 100 in FIG. 1. The multiphase power converter system 200 includes a first power converter circuit 202 and a second power converter circuit 204. However, in other examples, the multiphase power converter system 200 can include more than two power converter circuits, for example, N power converter circuits, where N is any integer. In some examples, the power converter circuit 202 can correspond to the power converter circuit 102a in FIG. 1 and the power converter circuit 204 can correspond to the power converter circuit 102n in FIG. 1. In this example, the first power converter circuit 202 and the second power converter circuit 204 include buck converter circuits. However, in other examples, the first power converter circuit 202 and the second power converter circuit 204 may be implemented differently.

In this example, the operation of the multiphase power converter system 200 in a pulse frequency modulation (PFM) mode is explained. However, the multiphase power converter system 200 can operate in pulse width modulation (PWM) mode as well. An output terminal 206 of the first power converter circuit 202 and an output terminal 208 of the second power converter circuit 204 are coupled to a common output terminal 210. The first power converter circuit 202 includes a first power stage 212 and a first inductor 214 coupled in series to an output of the first power converter circuit 202. The first power stage 212 includes a high-side switch HS and a low-side switch LS which are configured to be turned on and turned off in order to provide a first inductor current IL1 at the output terminal 206. In some examples, in the first power stage 212, when the high-side switch HS is turned on, the low-side switch LS is turned off, and vice-versa. In some examples, the first power stage 212 further includes a switch controller SC configured to control the turning on and turning off of the high-side switch HS and the low-side switch LS.

The second power converter circuit 204 includes a second power stage 216 and a second inductor 218 coupled in series to an output of the second power converter circuit 204. The second power stage 216 includes a high-side switch HS and a low-side switch LS which are configured to be turned on and turned off in order to provide a second inductor current IL2 at the output terminal 208. In some examples, in the second power stage 216, when the high-side switch HS is turned on, the low-side switch LS is turned off, and vice-versa. In some examples, the second power stage 216 further includes a switch controller SC configured to control the turning on and turning off of the high-side switch HS and the low-side switch LS. The multiphase power converter system 200 further includes a first control logic circuit 220 that is coupled to the first power converter circuit 202 and a second control logic circuit 222 that is coupled to the second power converter circuit 204. In particular, a pulse output terminal 224 of the first control logic circuit 220 is coupled to a pulse input terminal 226 of the first power converter circuit 202. Similarly, a pulse output terminal 228 of the second control logic circuit 222 is coupled to a pulse input terminal 230 of the second power converter circuit 204. In other examples, where there are more than two power converter circuits, the multiphase power converter system 200 will include more than two control logic circuits. In particular, each power converter circuit would have a corresponding control logic circuit associated therewith.

The first control logic circuit 220 is configured to provide a first PFM pulse signal PFM1 (e.g., a PFM pulse) via the pulse output terminal 224 to the pulse input terminal 226 of the first power converter circuit 202 during a first time period. The high-side switch HS and the low-side switch LS within the first power stage 212 are turned on and turned off during the first time period based on the first PFM pulse signal PFM1. The first control logic circuit 220 further includes a PFM control output terminal 232 that is coupled to a PFM control input terminal 234 of the first power converter circuit 202. The first control logic circuit 220 is configured to provide a first PFM control signal PFM_CTRL1 via the PFM control output terminal 232 to the PFM control input terminal 234 of the first power converter circuit 202. In some examples, the first PFM control signal PFM_CTRL1 is de-asserted (e.g., logic LOW) during the first time period such that both the high-side switch HS and the low-side switch LS within the first power stage 212 are controlled (e.g., turned on or turned off) based on the value of the first PFM pulse signal PFM1. At other time periods, the first PFM control signal PFM_CTRL1 is asserted (e.g., logic HIGH) such that both the high-side switch HS and the low-side switch LS within the first power stage 212 are turned off. In some examples, the switch controller SC within the first power stage 212 is configured to control the turning on and turning off of the high-side switch HS and the low-side switch LS based on the first PFM pulse signal PFM1 and the first PFM control signal PFM_CTRL1.

Further, the second control logic circuit 222 is configured to provide a second PFM pulse signal PFM2 (e.g., a PFM pulse) via the pulse output terminal 228 to the pulse input terminal 230 of the second power converter circuit 204 during a second time period. The high-side switch HS and the low-side switch LS within the second power stage 216 are turned on and turned off during the second time period based on the second PFM pulse signal PFM2. The second control logic circuit 222 further includes a PFM control output terminal 236 that is coupled to a PFM control input terminal 238 of the second power converter circuit 204. The second control logic circuit 222 is configured to provide a second PFM control signal PFM_CTRL2 via the PFM control output terminal 236 to the PFM control input terminal 238 of the second power converter circuit 204. In some examples, the second PFM control signal PFM_CTRL2 is de-asserted (e.g., logic LOW) during the second time period such that both the high-side switch HS and the low-side switch LS within the second power stage 216 are controlled (e.g., turned on or turned off) based on the value of the second PFM pulse signal PFM2. At other time periods, the second PFM control signal PFM_CTRL1 is asserted (e.g., logic HIGH) such that both the high-side switch HS and the low-side switch LS within the second power stage 216 are turned off. In some examples, the switch controller SC within the second power stage 216 is configured to control the turning on and turning off of the high-side switch HS and the low-side switch LS based on the second PFM pulse signal PFM2 and the second PFM control signal PFM_CTRL2.

The multiphase power converter system 200 further includes a pulse frequency modulation (PFM) timer circuit 240 having a PFM timer output terminal 242 that is coupled to a PFM input terminal 244 of the first control logic circuit 220 and a PFM input terminal 246 of the second control logic circuit 222. The PFM timer circuit 240 is configured to generate a PFM timer signal PFM_TIMER at the PFM timer output terminal 242 based on the voltage control signal V_CTRL at a voltage input terminal 250 and a PFM reset signal PFM_RESET at the reset terminal 254. The PFM timer circuit 240 is further configured to provide the PFM timer signal PFM_TIMER to the first control logic circuit 220 and the second control logic circuit 222. In some examples, the PFM timer signal PFM_TIMER determines a frequency of the first PFM pulse signal PFM1 and the second PFM pulse signal PFM2.

The first control logic circuit 220 includes a PFM reset signal generation circuit (not shown) that is configured to generate the PFM reset signal PFM_RESET such that the PFM reset signal PFM_RESET is set to a logic high state when any one of the control logic circuits (e.g., the first control logic circuit 220 or the second control logic circuit 222) starts generating PFM pulses (e.g., the first PFM pulse signal PFM1 or the second PFM pulse signal PFM2). The PFM reset signal PFM_RESET includes a pulse signal of short duration. More particularly, the PFM reset signal PFM_RESET will be in a logic HIGH state only for a short duration (e.g., 20 ns) compared to the first time period (e.g., 500 ns) when the first PFM pulse signal PFM1 is generated or the second time period (e.g., 500 ns) when the second PFM pulse signal PFM2 is generated. In other examples, the PFM reset signal generation circuit may be implemented external to the first control logic circuit 220. The PFM reset signal generation circuit is configured to generate the PFM reset signal PFM_RESET based on respective pulse generation indication signals (also referred to as PFM pulse generation indication signals) received from the first control logic circuit 220 and the second control logic circuit 222. In some examples, the respective PFM pulse generation indication signals provides an indication of whether the corresponding control logic circuit has started generating the PFM pulses or not. In this example, the first control logic circuit 220 is configured to provide a respective PFM pulse generation indication signal (not shown) and the second control logic circuit 222 is configured to provide a respective PFM pulse generation indication signal PFM_IND to the PFM reset signal generation circuit.

Further, the first control logic circuit 220 includes a PFM rotator circuit (not shown) configured to provide a first PFM rotator signal (not shown) and a second PFM rotator signal PFM_ROT2. In some examples, the first control logic circuit 220 is configured to determine the first time period during which to generate/provide the first PFM pulse signal PFM1 based on the first PFM rotator signal. In particular, the first control logic circuit 220 is configured to provide the first PFM pulse signal PFM1 only when the first PFM rotator signal is active (e.g., in a logic HIGH state). Similarly, the second control logic circuit 222 is configured to determine the second time period during which to generate/provide the second PFM pulse signal PFM2 based on the second PFM rotator signal PFM_ROT2. In particular, the second control logic circuit 222 is configured to provide the second PFM pulse signal PFM2 only when the second PFM rotator signal PFM_ROT2 is active (e.g., in a logic HIGH state). In some examples, the PFM rotator circuit is configured to determine the respective time period during which the first PFM rotator signal and the second PFM rotator signal PFM_ROT2 are active, based on the PFM timer signal PFM_TIMER. For example, the first PFM rotator signal and the second PFM rotator signal PFM_ROT2 are configures to change state from a logic HIGH state to a logic LOW state, or vice versa, at a falling edge of the PFM timer signal PFM_TIMER. In some examples, the first control logic circuit 220 and the second control logic circuit 222 are configured to generate/provide the first PFM pulse signal PFM1 during the first time period and the second PFM pulse signal PFM2 during the second time period, respectively, further based on the PFM timer signal PFM_TIMER, as further explained in examples below.

The multiphase power converter system 200 further includes a first current sense comparator circuit 262 that is coupled to the first control logic circuit 220 and a second current sense comparator circuit 264 that is coupled to the second control logic circuit 222. In other examples, where there are more than two control logic circuits, the multiphase power converter system 200 will include more than two current sense comparator circuits. In particular, each control logic circuit would have a corresponding current sense comparator circuit associated therewith. The first current sense comparator circuit 262 includes a peak current comparator circuit 266 and a valley current comparator circuit 268. The peak current comparator circuit 266 is configured to generate a first peak current control signal PK_CTRL1 at an output 270 and provide the first peak current control signal PK_CTRL1 to the first control logic circuit 220. The valley current comparator circuit 268 is configured to generate a first valley current control signal VL_CTRL1 at an output 272 and provide the first valley current control signal VL_CTRL1 to the first control logic circuit 220. The first control logic circuit 220 is configured to generate the first PFM pulse signal PFM1 based on the first peak current control signal PK_CTRL1 and the first valley current control signal VL_CTRL1.

The peak current comparator circuit 266 is configured to generate the first peak current control signal PK_CTRL1 based on a first output current I_{OUT1} associated with the first power converter circuit 202. In particular, the peak current comparator circuit 266 is configured to generate the first peak current control signal PK_CTRL1 based on a comparison of the first output current I_{OUT1} and a peak reference current I_{PREF}. Similarly, the valley current comparator circuit 268 is configured to generate the first valley current control signal VL_CTRL1 based on the first output current I_{OUT1} associated with the first power converter circuit 202. In particular, the valley current comparator circuit 268 is configured to generate the first valley current control signal VL_CTRL1 based on a comparison of the first output current I_{OUT1} and a valley reference current I_{VREF}. In some examples, the first output current I_{OUT1} may correspond to a current at the output of the power stage 212. Alternately, in other examples, the first output current I_{OUT1} may correspond to the first inductor current IL1 at the output terminal 206.

Further, the second current sense comparator circuit 264 includes a peak current comparator circuit 274 and a valley current comparator circuit 276. The peak current comparator circuit 274 is configured to generate a second peak current control signal PK_CTRL2 at an output 278 and provide the second peak current control signal PK_CTRL2 to the second control logic circuit 222. The valley current comparator circuit 276 is configured to generate a second valley current control signal VL_CTRL2 at an output 280 and provide the second valley current control signal VL_CTRL2 to the second control logic circuit 222. The second control logic circuit 222 is configured to generate the second PFM pulse signal PFM2 based on the second peak current control signal PK_CTRL2 and the second valley current control signal valley_ctrl2.

The peak current comparator circuit 274 is configured to generate the second peak current control signal PK_CTRL2 based on a second output current I_{OUT2} associated with the second power converter circuit 204. In particular, the peak current comparator circuit 274 is configured to generate the second peak current control signal PK_CTRL2 based on a comparison of the second output current I_{OUT2} and the peak reference current I_{PREF}. Similarly, the valley current comparator circuit 276 is configured to generate the second valley current control signal VL_CTRL2 based on the second output current I_{OUT2} associated with the second power converter circuit 204. In particular, the valley current comparator circuit 276 is configured to generate the second valley current control signal VL_CTRL2 based on a comparison of the second output current I_{OUT2} and the valley reference current I_{VREF}. In some examples, the second output current I_{OUT2} may correspond to a current at the output of the power stage 216. Alternately, in other examples, the second output current I_{OUT2} may correspond to the second inductor current IL2 at the output terminal 208.

The first current sense comparator circuit 262 and the second current sense comparator circuit 264 are enabled only during the time periods when the corresponding control logic circuits are generating the respective PFM pulses. For example, the first current sense comparator circuit 262 is enabled during the first time period when the first PFM control signal PFM_CTRL1 is in the de-asserted state or the logic LOW state such that the first PFM pulse signal PFM1 is generated during the first time period. Further, the first current sense comparator circuit 262 is disabled at other time periods when the first PFM control signal PFM_CTRL1 is in the asserted state or the logic HIGH state such that the first PFM pulse signal PFM1 is not generated during the other time periods. Similarly, the second current sense comparator circuit 264 is enabled during the second time period when the second PFM control signal PFM_CTRL2 is in the de-asserted state or the logic LOW state such that the second PFM pulse signal PFM2 is generated during the second time period. Further, the second current sense comparator circuit 264 is disabled at other time periods when the second PFM control signal PFM_CTRL2 is in the asserted state or the logic HIGH state such that the second PFM pulse signal PFM2 is not generated during the other time periods. To accomplish this feature, the first control logic circuit 220 is configured to generate a first current sense enable signal EN1 to enable or disable the first current sense comparator circuit 262 and provide the first current sense enable signal EN1 to the first current sense comparator circuit 262. Similarly, the second control logic circuit 222 is configured to generate a second current sense enable signal EN2 to enable or disable the second current sense comparator circuit 264 and provide the second current sense enable signal EN2 to the second current sense comparator circuit 264.

The multiphase power converter system 200 further includes a voltage compensation circuit 282 configured to generate a voltage control signal V_CTRL at an output terminal 284 based on a comparison of a feedback voltage V_fb and an output reference voltage V_ref. The voltage compensation circuit 282 includes a voltage comparator circuit 283 configured to provide the voltage control signal V_CTRL based on the feedback voltage V_fb and the output reference voltage V_ref. The voltage compensation circuit 282 further includes a resistor 285 and a capacitor 287 that are coupled in series to one another. The series combination of the resistor 295 and the capacitor 287 is coupled to an output of the voltage comparator circuit 283. In some examples, the feedback voltage V_fb is indicative of an output voltage Vout at the common output terminal 210. Furthermore, the multiphase power converter system 200 includes a reference current generation circuit 286 that is coupled to the output terminal 284 of the voltage compensation circuit 282 and configured to generate the peak reference current I_{PREF} and the valley reference current I_{VREF} based on the voltage control signal V_CTRL.

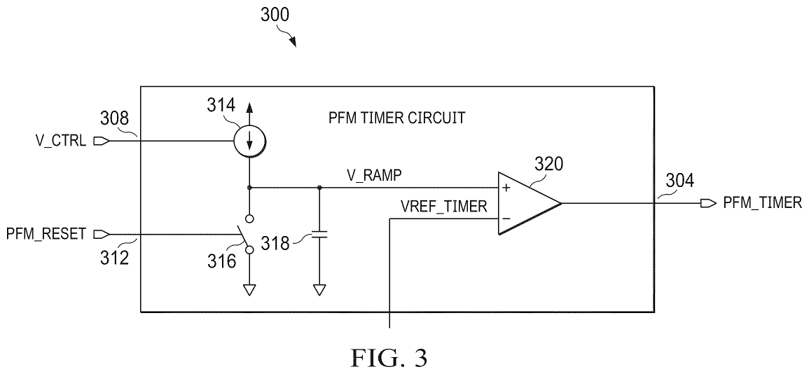

FIG. 3 illustrates an example implementation of a PFM timer circuit 300. The PFM timer circuit 300 depicts one possible way of implementation of the PFM timer circuit 116 in FIG. 1 and the PFM timer circuit 240 in FIG. 2 and is explained herein with reference to the PFM timer circuit 240 in FIG. 2. The PFM timer circuit 300 is configured to generate a PFM timer signal PFM_TIMER at a PFM timer output terminal 304 based on a voltage control signal V_CTRL at a voltage input terminal 308 and a PFM reset signal PFM_RESET at a reset terminal 312. In some examples, the PFM timer signal PFM_TIMER corresponds to the PFM timer signal PFM_TIMER in FIG. 2, the voltage control signal V_CTRL corresponds to the voltage control signal V_CTRL in FIG. 2 and PFM reset signal PFM_RESET corresponds to the PFM reset signal PFM_RESET in FIG. 2. The PFM timer circuit 300 includes a current source 314, a reset switch 316, a capacitor 318 and a comparator 320. The current source 314 is configured to provide a charging current based on the voltage control signal V_CTRL. The reset switch 316 is controlled based on the PFM reset signal PFM_RESET. For example, when the PFM reset signal PFM_RESET is in a logic HIGH state, the reset switch 316 is turned ON and when the PFM reset signal PFM_RESET is in a logic LOW state, the reset switch 316 is turned OFF.

Based on the turning on and turning off of the reset switch 316, a voltage ramp signal (also referred to as a PFM voltage ramp signal) V_RAMP that includes a sawtooth waveform is generated at a first input of the comparator 320. In particular, when the reset switch 316 is turned off, the capacitor 318 is charged based on the charging current thereby forming the rising portion or the ramp portion of the sawtooth waveform and when the reset switch 316 is turned on, the capacitor is discharged to the ground thereby forming the falling portion of the sawtooth waveform. The comparator 320 is configured to generate the PFM timer signal PFM_TIMER based on a comparison of the PFM voltage ramp signal V_RAMP and a timer reference voltage (also referred to as a PFM timer reference voltage) VREF_TIMER. The PFM timer signal PFM_TIMER has a triggered state (e.g., a logic HIGH state) and a reset state (e.g., a logic LOW state). The PFM timer signal PFM_TIMER is transitioned to the triggered state when the PFM voltage ramp signal V_RAMP is greater than the PFM timer reference voltage VREF_TIMER, and the PFM timer signal PFM_TIMER is transitioned to the reset state when the PFM voltage ramp signal V_RAMP is less than the PFM timer reference voltage VREF_TIMER. The PFM timer signal PFM_TIMER transitions to the reset state during the falling portion the PFM voltage ramp signal V_RAMP. In some examples, the PFM voltage ramp signal V_RAMP is modified to form the falling portion based on the PFM reset signal PFM_RESET, in particular, when the PFM reset signal PFM_RESET is in the logic HIGH state. In some examples, the PFM reset signal PFM_RESET is transitioned to the logic HIGH state when any one of the control logic circuits (e.g., either the first control logic circuit 220 or the second control logic circuit 222) starts generating the respective PFM pulses. The PFM reset signal PFM_RESET is transitioned to the logic HIGH state only for a very short duration of time (thereby forming a PFM reset pulse) in response to any one of the control logic circuits starting to generate the respective PFM pulses. Thereafter the PFM reset signal PFM_RESET transitions back to the logic LOW state, until another one of the control logic circuits starts generating the respective PFM pulses.

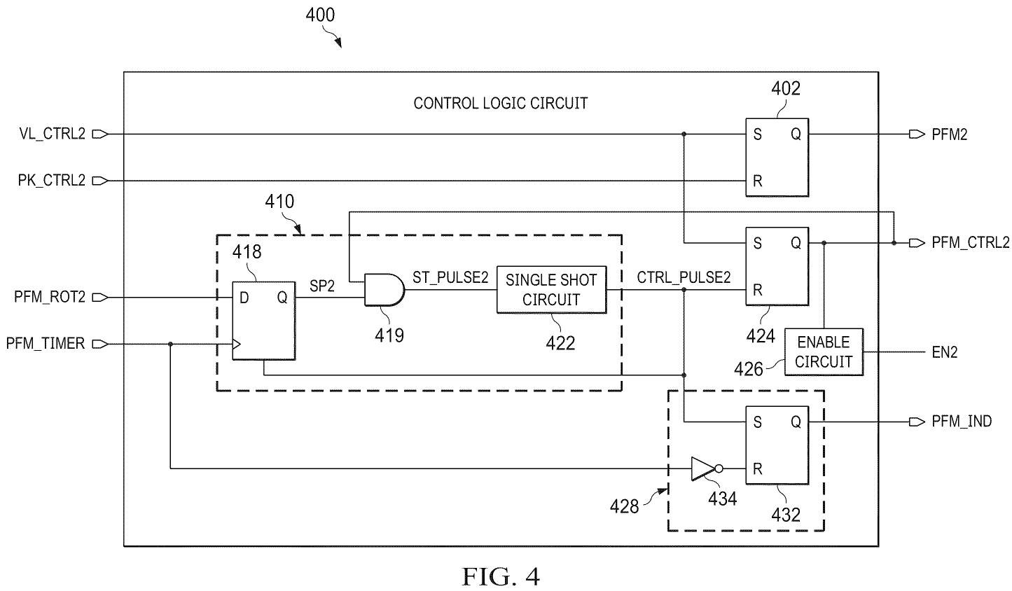

FIG. 4 illustrates an example implementation of a control logic circuit 400. In some examples, the control logic circuit 400 depicts one possible way of implementation of the second control logic circuit 222 in FIG. 2 and the control logic circuit 108n in FIG. 1. The control logic circuit 400 is explained herein with reference to the second control logic circuit 222 in FIG. 2. The control logic circuit 400 includes a PFM pulse generation circuit 402 configured to generate a PFM pulse signal PFM2 (e.g., corresponding to the second PFM pulse signal PFM2 in FIG. 2) based on a valley current control signal VL_CTRL2 (e.g., corresponding to the valley current control signal VL_CTRL2 in FIG. 2) and a peak current control signal PK_CTRL2 (e.g., corresponding to the peak current control signal PK_CTRL2 in FIG. 2). In this example, the PFM pulse generation circuit 402 includes an SR latch configured to receive the valley current control signal VL_CTRL2 at the S input and receive the peak current control signal PK_CTRL2 at the R input. In some examples, the control logic circuit 400 may be configured to generate the PFM pulse signal PFM2 based on the valley current control signal VL_CTRL2 and the peak current control signal PK_CTRL2 during a PFM mode. The control logic circuit 400 may further be configured to generate PWM pulses (not shown) based on the valley current control signal VL_CTRL2 and the peak current control signal PK_CTRL2 during a PWM mode.

The control logic circuit 400 further includes a control pulse generation circuit 410 configured to generate a control pulse signal CTRL_PULSE2 based on a PFM rotator signal PFM_ROT2 (e.g., corresponding to the second PFM rotator signal PFM_ROT2 in FIG. 2) and a PFM timer signal PFM_TIMER (e.g., corresponding to the PFM timer signal PFM_TIMER in FIG. 2). Further, the control logic circuit 400 includes a PFM control signal generation circuit 424 configured to generate a PFM control signal PFM_CTRL2 (e.g., corresponding to the second PFM control signal PFM_CTRL2 in FIG. 2) based on the control pulse signal CTRL_PULSE2 and the valley current control signal VL_CTRL2. In this example, the PFM control signal generation circuit 424 is implemented using an SR latch that receives the valley current control signal VL_CTRL2 at the S input and receives the control pulse signal CTRL_PULSE2 at the R input. In some examples, the PFM control signal PFM_CTRL2 is transitioned to an enabled/de-asserted state (e.g., logic LOW) when the control pulse signal CTRL_PULSE2 is in a logic HIGH state and the valley current control signal VL_CTRL2 is in a logic LOW state. Further, the PFM control signal PFM_CTRL2 is transitioned to a disabled/asserted state (e.g., logic HIGH) when the control pulse signal CTRL_PULSE2 is in a logic LOW state and the valley current control signal VL_CTRL2 is in a logic HIGH state.

In some examples, the control pulse signal CTRL_PULSE2 includes a pulse signal of a short duration (e.g., the CTRL_PULSE2 is in a logic HIGH state only for a short duration, for example, 20 ns). The control pulse signal CTRL_PULSE2 is transitioned to a logic HIGH state when the PFM rotator signal PFM_ROT2 is active, the PFM timer signal PFM_TIMER is in the triggered state and the PFM control signal PFM_CTRL2 is in the logic HIGH state. The control pulse signal CTRL_PULSE2 subsequently goes into a logic LOW state after a short delay (e.g., 20 ns). The control pulse generation circuit 410 includes a start PFM indicator circuit 418 configured to generate a start pulse SP2 based on the PFM rotator signal PFM_ROT2 and the PFM timer signal PFM_TIMER. In this example, the start PFM indicator circuit 418 is implemented as a D Flip Flop. However, in other examples, the start PFM indicator circuit 418 could be implemented differently. The start pulse SP2 is transitioned to a logic HIGH state when the PFM rotator signal PFM_ROT2 is active and the PFM timer signal PFM_TIMER is in the triggered state. The control pulse generation circuit 410 further includes a pulse AND gate 419 configured to provide a start PFM pulse ST_PULSE2 based on the start pulse SP2 and the PFM control signal PFM_CTRL2. At the time the start pulse SP2 is transitioned to the logic HIGH state, the PFM control signal PFM_CTRL2 is in an asserted state or a logic HIGH state. Therefore, the start PFM pulse ST_PULSE2 is in a logic HIGH state. The control pulse generation circuit 410 further includes a single shot circuit 422 configured to generate the control pulse signal CTRL_PULSE2 based on the start PFM pulse ST_PULSE2. In particular, the control pulse signal CTRL_PULSE2 is transitioned to a logic HIGH state at the rising edge of the start PFM pulse ST_PULSE2. Further, the PFM control signal PFM_CTRL2 is transitioned to a de-asserted state or a logic LOW state based on the control pulse signal CTRL_PULSE2 (e.g., when the control pulse signal CTRL_PULSE2 is transitioned into the logic HIGH state). In some examples, the control pulse signal CTRL_PULSE2 is further provided to the start PFM indicator circuit 418. When the CTRL_PULSE2 is in the logic HIGH state, the start PFM indicator circuit 418 is reset thereby transitioning the start pulse SP2 to a logic LOW state. When the start pulse SP2 and the PFM control signal PFM_CTRL2 are in the logic LOW state, the start PFM pulse ST_PULSE2 (at the output of the pulse AND gate 419) is transitioned to the logic LOW state.

In some examples, a high-side switch and a low side switch of the associated power stage are controlled (e.g., turned on or turned off) based on the PFM pulse signal PFM2 when the PFM control signal PFM_CTRL2 is in the de-asserted state (e.g., the logic LOW state). Further, the high-side switch and the low side switch of the associated power stage are turned off when the PFM control signal PFM_CTRL2 is in the asserted state (e.g., the logic HIGH state). When the high-side switch and the low side switch of the associated power stage are turned off, the power stage is configured not to provide any output current. Further, when the high-side switch and the low side switch of the associated power stage are controlled based on the PFM pulse signal PFM2, the power stage is configured to provide an output current (e.g., the second output current I_{OUT2} in FIG. 2).

The control logic circuit 400 is further configured to generate a current sense enable signal EN2 (e.g., the second current sense enable signal EN2 in FIG. 2) that enables or disables a current sense comparator circuit (e.g., the second current sense comparator circuit 264 in FIG. 2). For example, the current sense comparator circuit is enabled when the current sense enable signal is active and the current sense comparator circuit is disabled when the current sense enable signal is inactive. In some examples, the current sense enable signal is generated based on the control pulse signal CTRL_PULSE2 and/or the PFM control signal PFM_CTRL2. In particular, the current sense enable signal is transitioned to the active state when the PFM control signal PFM_CTRL2 is transitioned to the de-asserted state (e.g., the logic LOW state) and the current sense enable signal is transitioned to the inactive state when the PFM control signal PFM_CTRL2 is transitioned to the asserted state (e.g., the logic HIGH state). In this example, the control logic circuit 400 includes an enable circuit 426 configured to generate the current sense enable signal EN2 based on the PFM control signal PFM_CTRL2.

The control logic circuit 400 further includes a pulse generation indication circuit 428 configured to provide/generate a PFM pulse generation indication signal PFM_IND (e.g., the PFM pulse generation indication signal PFM_IND in FIG. 2) based on the control pulse signal CTRL_PULSE2 and the PFM timer signal PFM_TIMER. In some examples, the PFM pulse generation indication signal PFM_IND provides an indication of whether the control logic circuit 400 has started generating the PFM pulse signal PFM2. In this example, the pulse generation indication circuit 428 is implemented using an SR latch 432 configured to receive the control pulse signal CTRL_PULSE2 at the S input and an inverted version of the PFM timer signal PFM_TIMER at the R input. The pulse generation indication circuit 428 further includes an inverter circuit 434 configured to provide the inverted version of the PFM timer signal PFM_TIMER to the R input of the SR latch 432.

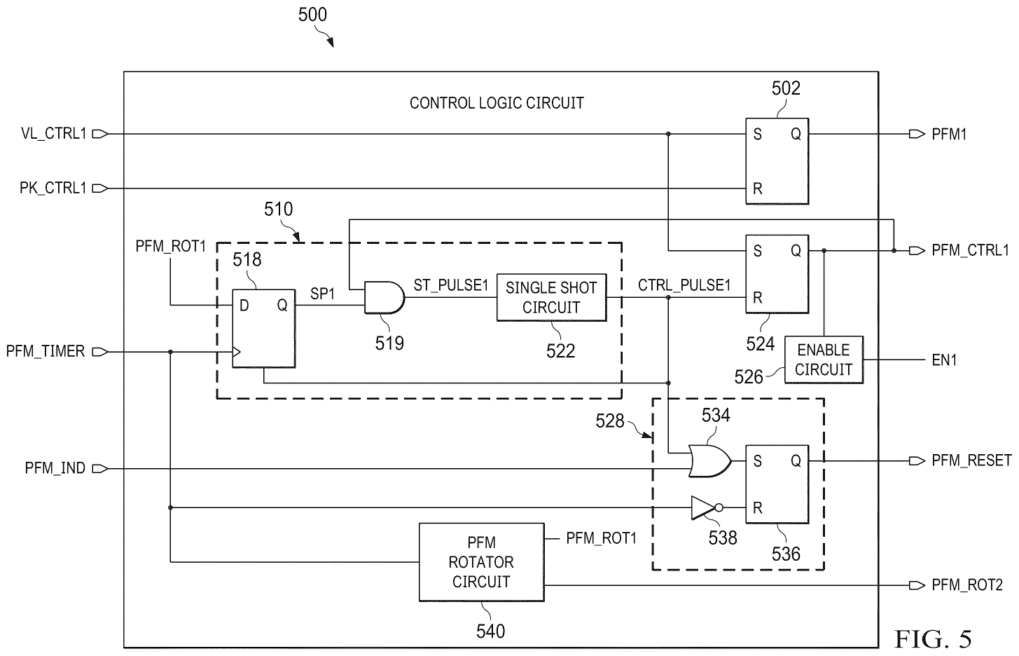

FIG. 5 illustrates another example implementation of a control logic circuit 500. In some examples, the control logic circuit 500 depicts one possible way of implementation of the first control logic circuit 220 in FIG. 2 and the control logic circuit 108a in FIG. 1. The control logic circuit 500 is explained herein with reference to the first control logic circuit 220 in FIG. 2. The control logic circuit 500 includes a PFM pulse generation circuit 502 configured to generate a PFM pulse signal PFM1 (e.g., corresponding to the first PFM pulse signal PFM1 in FIG. 2) based on a valley current control signal VL_CTRL1 (e.g., corresponding to the valley current control signal VL_CTRL1 in FIG. 2) and a peak current control signal PK_CTRL1 (e.g., corresponding to the peak current control signal PK_CTRL1 in FIG. 2). In this example, the PFM pulse generation circuit 502 includes an SR latch configured to receive the valley current control signal VL_CTRL1 at the S input and receive the peak current control signal PK_CTRL1 at the R input. In other examples, the PFM pulse generation circuit 502 may be implemented differently. In some examples, the control logic circuit 500 may be configured to generate the PFM pulse signal PFM1 based on the valley current control signal VL_CTRL1 and the peak current control signal 808 during a PFM mode. The control logic circuit 500 may further be configured to generate PWM pulses (not shown) based on the valley current control signal VL_CTRL1 and the peak current control signal PK_CTRL1 during a PWM mode.

The control logic circuit 500 further includes a control pulse generation circuit 510 configured to generate a control pulse signal CTRL_PULSE1 based on a PFM rotator signal PFM_ROT1 (e.g., corresponding to the first PFM rotator signal PFM_ROT 1 in FIG. 1) and a PFM timer signal PFM_TIMER (e.g., corresponding to the PFM timer signal PFM_TIMER in FIG. 2). Further, the control logic circuit 500 includes a PFM control signal generation circuit 524 configured to generate a PFM control signal PFM_CTRL1 (e.g., corresponding to the first PFM control signal PFM_CTRL1 in FIG. 2) based on the control pulse signal CTRL_PULSE1 and the valley current control signal VL_CTRL1. In this example, the PFM control signal generation circuit 524 is implemented using an SR latch that receives the valley current control signal VL_CTRL1 at the S input and receives the control pulse signal CTRL_PULSE1 at the R input. In other examples, the PFM control signal generation circuit 524 may be implemented differently. In some examples, the PFM control signal PFM_CTRL1 is transitioned to an enabled/de-asserted state (e.g., a logic LOW state) when the control pulse signal CTRL_PULSE1 is in a logic HIGH state and the valley current control signal VL_CTRL1 is in a logic LOW state. Further, the PFM control signal PFM_CTRL1 is transitioned to a disabled/asserted state (e.g., a logic HIGH state) when the control pulse signal CTRL_PULSE2 is in a logic LOW state and the valley current control signal VL_CTRL1 is in a logic HIGH state.

In some examples, the control pulse signal CTRL_PULSE1 includes a pulse signal of a short duration (e.g., the CTRL_PULSE1 is in a logic HIGH state only for a short duration, for example, 20 ns). The control pulse signal CTRL_PULSE1 is transitioned to a logic HIGH state when the PFM rotator signal PFM_ROT1 is active, the PFM timer signal PFM_TIMER is in the triggered state and the PFM control signal PFM_CTRL1 is in a logic HIGH state. The control pulse signal CTRL_PULSE1 subsequently goes into a logic LOW state after a short delay (e.g., 20 ns). The control pulse generation circuit 510 includes a start PFM indicator circuit 518 configured to generate a start pulse SP1 based on the PFM rotator signal PFM_ROT1 and the PFM timer signal PFM_TIMER. In this example, the start PFM indicator circuit 518 is implemented as a D Flip Flop. In other examples, the start PFM indicator circuit 518 may be implemented differently. The start pulse SP1 is transitioned to a logic HIGH state when the PFM rotator signal PFM_ROT1 is active and the PFM timer signal PFM_TIMER is in the triggered state. The control pulse generation circuit 510 further includes a pulse AND gate 519 configured to provide a start PFM pulse ST_PULSE1 based on the start pulse SP1 and the PFM control signal PFM_CTRL1. At the time the start pulse SP1 is transitioned to the logic HIGH state, the PFM control signal PFM_CTRL1 is in an asserted state or a logic HIGH state. Therefore, the start PFM pulse ST_PULSE1 is in a logic HIGH state. The control pulse generation circuit 510 further includes a single shot circuit 522 configured to generate the control pulse signal CTRL_PULSE1 based on the start PFM pulse ST_PULSE1. In particular, the control pulse signal CTRL_PULSE1 is transitioned to a logic HIGH state at the rising edge of the start PFM pulse ST_PULSE1. Further, the PFM control signal PFM_CTRL1 is transitioned to the de-asserted state or a logic LOW state based on the control pulse signal CTRL_PULSE1 (e.g., when the control pulse signal CTRL_PULSE1 is transitioned into the logic HIGH state). In some examples, the control pulse signal CTRL_PULSE1 is further provided to the start PFM indicator circuit 518. When the CTRL_PULSE1 is in the logic HIGH state, the start PFM indicator circuit 518 is reset thereby transitioning the start pulse SP1 to a logic LOW state. When the start pulse SP1 and the PFM control signal PFM_CTRL1 are in the logic LOW state, the start PFM pulse ST_PULSE1 (at the output of the pulse AND gate 519) is transitioned to the logic LOW state.

In some examples, a high-side switch and a low side switch of the associated power stage are controlled (e.g., turned on or turned off) based on the PFM pulse signal PFM1 when the PFM control signal PFM_CTRL1 is in the de-asserted state (e.g., the logic LOW state). Further, the high-side switch and the low side switch of the associated power stage are turned off when the PFM control signal PFM_CTRL1 is in the asserted state (e.g., the logic HIGH state). When the high-side switch and the low side switch of the associated power stage are turned off, the power stage is configured not to provide any output current. Further, when the high-side switch and the low side switch of the associated power stage are controlled based on the PFM pulse signal PFM1, the power stage is configured to provide an output current (e.g., the first output current Iouri in FIG. 2).

The control logic circuit 500 is further configured to generate a current sense enable signal EN1 (e.g., the first current sense enable signal EN1 in FIG. 2) that facilitates to enable or disable a current sense comparator circuit (e.g., the first current sense comparator circuit 262 in FIG. 2). For example, the current sense comparator circuit is enabled when the current sense enable signal is active and the current sense comparator circuit is disabled when the current sense enable signal is inactive. In some examples, the current sense enable signal is generated based on the control pulse signal CTRL_PULSE1 and/or the PFM control signal PFM_CTRL1. In particular, the current sense enable signal is transitioned to the active state when the PFM control signal PFM_CTRL1 is transitioned to the de-asserted state (e.g., the logic LOW state) and the current sense enable signal is transitioned to the inactive state when the PFM control signal PFM_CTRL1 is transitioned to the asserted state (e.g., the logic HIGH state). In this example, the control logic circuit 500 includes an enable circuit 526 configured to generate the current sense enable signal EN1 based on the PFM control signal PFM_CTRL1.

The control logic circuit 500 further includes a PFM reset signal generation circuit 528 configured to generate the PFM reset signal PFM_RESET (e.g., the PFM reset signal PFM_RESET in FIG. 2) based on the control pulse signal CTRL_PULSE1, a pulse generation indication signal PFM_IND (e.g., corresponding to the pulse generation indication signal PFM_IND in FIG. 2 or the pulse generation indication signal PFM_IND in FIG. 4) and the PFM timer signal PFM_TIMER. In this example, the PFM reset signal generation circuit 528 is implemented as part of the control logic circuit 500. Alternately, in other examples, the PFM reset signal generation circuit 528 may be implemented external to the control logic circuit 500. In this example, since the PFM reset signal generation circuit 528 is implemented as part of the control logic circuit 500, the control pulse signal CTRL_PULSE1 provides an indication of whether the control logic circuit 500 has started generating the PFM pulse signal PFM1. The PFM reset signal PFM_RESET is set to a logic HIGH state when either the control pulse signal CTRL_PULSE1 or the pulse generation indication signal PFM_IND provides an indication that the corresponding control logic circuit has started generating the respective PFM pulses.

The PFM reset signal generation circuit 528 includes an OR gate 534 configured to receive 2 inputs, that is, the control pulse signal CTRL_PULSE1 and the pulse generation indication signal PFM_IND and provide an output based thereon. In other examples, the OR gate 534 may be configured to receive more than 2 inputs, depending on the number of control logic circuits included within the associated multiphase power converter system (e.g., the multiphase power converter system 200 in FIG. 2). The PFM reset signal generation circuit 528 further includes an SR latch 536 configured to receive the output of the OR gate 534 at the S input and an inverted version of the PFM timer signal PFM_TIMER at the R input. Furthermore, the PFM reset signal generation circuit 528 includes an inverter 538 configured to provide the inverted version of the PFM timer signal PFM_TIMER to the R input of the SR latch 536. In the examples where the PFM reset signal generation circuit 528 is implemented external to the control logic circuit 500, the control logic circuit 500 may include a pulse generation indication circuit (similar to that explained above with respect to FIG. 4) configured to provide/generate a corresponding PFM pulse generation indication signal to the PFM reset signal generation circuit 528.

The control logic circuit 500 further includes a PFM rotator circuit 540 configured to generate the PFM rotator signal PFM_ROT1 and another PFM rotator signal PFM_ROT2 (e.g., the second PFM rotator signal PFM_ROT2 in FIG. 2), based on the PFM timer signal PFM_TIMER. In some examples, the PFM rotator signal PFM_ROT1 and the PFM rotator signal PFM_ROT2 are transitioned between an active state (e.g., a logic HIGH state) and an inactive state (e.g., a logic LOW state), or vice-versa, at the falling edge of the PFM timer signal PFM_TIMER. In some examples, the PFM rotator signal PFM_ROT1 and the PFM rotator signal PFM_ROT2 are transitioned to the active state at different (e.g., non-overlapping) time periods. In one example, the PFM rotator signal PFM_ROT1 is transitioned to the active state (e.g., a logic HIGH state) when the PFM timer signal PFM_TIMER is transitioned to the triggered state for a first time (in particular, at a falling edge of the PFM timer signal PFM_TIMER). Similarly, the PFM rotator signal PFM_ROT2 is transitioned to an active state (e.g., a logic HIGH state) when the PFM timer signal PFM_TIMER is transitioned to the triggered state the next time (in particular, at the falling edge of the PFM timer signal PFM_TIMER). In this example, the PFM rotator circuit 540 is implemented as part of the control logic circuit 500. However, in other examples, the PFM rotator circuit 540 may be implemented external to the control logic circuit 500. It is noted herein that in the multiphase power converter system 100 in FIG. 1 or the multiphase power converter system 200 in FIG. 2, only one of the control logic circuits (e.g., the control logic circuit 108a in FIG. 1 or the first control logic circuit 220 in FIG. 2) may be implemented as the control logic circuit 500 to include the PFM reset signal generation circuit 528 and/or the PFM rotator circuit 540. All the other control logic circuits, for example, any of the plurality of control logic circuits in FIG. 1, other than the control logic circuit 108a or the second control logic circuit 222 in FIG. 2 are implemented as the control logic circuit 400 in FIG. 4.

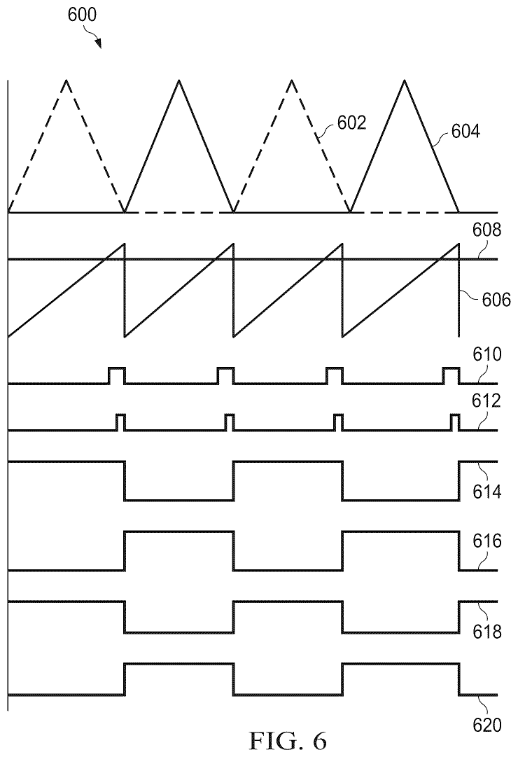

FIG. 6 illustrates a graph 600 that depicts various plots associated with a multiphase power converter system during a pulse frequency modulation (PFM) mode of operation. The plots are explained herein with reference to FIG. 2, FIG. 3, FIG. 4 and FIG. 5. The plot 602 depicts the first inductor current IL1 at the output terminal 206 of the first power converter circuit 202 in FIG. 2 and the plot 604 depicts the second inductor current IL2 at the output terminal 206 of the second power converter circuit 204 in FIG. 2. The plot 606 depicts the PFM voltage ramp signal V_RAMP in FIG. 3 and the plot 608 depicts the PFM timer reference voltage VREF_TIMER in FIG. 3. The plot 610 depicts the PFM timer signal PFM_TIMER in FIG. 3 and the plot 612 depicts the PFM reset signal PFM_RESET in FIG. 3. The plot 614 depicts the PFM rotator signal PFM_ROT1 associated with the first control logic circuit 220 in FIG. 2 and the plot 616 depicts the PFM rotator signal PFM_ROT2 associated with the second control logic circuit 222 in FIG. 2. The PFM_ROT1 and the PFM_ROT2 change state at the falling edge of the PFM timer signal PFM_TIMER. The plot 618 depicts the first current sense enable signal EN1 in FIG. 2 and the plot 620 depicts the second current sense enable signal EN2 in FIG. 2.

As can be seen in the plots 602 and 604, the first power converter circuit 202 and the second power converter circuit 204 are configured to generate the corresponding inductor currents IL1 and IL2, respectively, at different time periods (e.g., in an interleaved fashion). The first power converter circuit 202 and the second power converter circuit 204 are configured to generate the corresponding inductor currents IL1 and IL2, when the respective PFM pulses are generated. As can be seen in plots 610 and 614, the generation of the inductor current IL1 (or the corresponding PFM pulses) is started when the PFM timer signal PFM_TIMER is in the triggered state and the corresponding PFM rotator signal is in active state. Similarly, as can be seen in plots 610 and 616, the generation of the inductor current IL2 (or the corresponding PFM pulses) is started when the PFM timer signal PFM_TIMER is in the triggered state and the corresponding PFM rotator signal is in active state.

Further, as can be seen in plots 606, 608 and 610, the PFM timer signal PFM_TIMER is transitioned to the triggered state when the PFM voltage ramp signal V_RAMP is greater than the PFM timer reference voltage VREF_TIMER. Further, the PFM timer signal PFM_TIMER is transitioned to the reset state when the PFM voltage ramp signal V_RAMP is lesser than the PFM timer reference voltage VREF_TIMER. As can be seen in plot 612, the PFM reset signal PFM_RESET transitions to a logic HIGH state each time when the generation of the PFM pulses (or the corresponding inductor currents IL1 or IL2) associated with the first power converter circuit 202 or the second power converter circuit 204 are started. Furthermore, as can be seen in the plot 618, the first current sense enable signal EN1 is set to logic HIGH state when the first inductor current IL1 is generated, and the first current sense enable signal EN1 is set to logic LOW state when the first inductor current IL1 is not generated. Similarly, as can be seen in plot 620, the second current sense enable signal EN2 is set to logic HIGH state when the second inductor current IL2 is generated, and the second current sense enable signal EN2 is set to logic LOW state when the second inductor current IL2 is not generated.

In this description, the term “based on” means based at least in part on. In this description, the term “turned on”, as describing a transistor, refers to providing sufficient bias (e.g., gate-source voltage for a field-effect transistor (FET)) to operate the transistor device in resistive or saturation mode. Similarly, the term “turned off”, as describing a transistor, refers to removing bias to operate the transistor device in cutoff mode.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof. Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be configured to couple to at least some of the passive elements and/or the sources to form the described structure, either at a time of manufacture or after a time of manufacture, such as by an end user and/or a third party.

Modifications are possible in the described embodiments, and other embodiments are possible, within the scope of the claims.

What is claimed is:

1. A circuit comprising:
a plurality of control logic circuits, wherein each of the control logic circuits is configured to provide respective pulses at different time periods;
a timer circuit configured to provide a timer signal to each of the control logic circuits based on an output voltage, wherein the timer signal determines a frequency of the respective pulses; and
a rotator circuit configured to provide a plurality of rotator signals to the control logic circuits, respectively, wherein each control logic circuit is configured to determine a time period of the different time periods during which to generate the respective pulses based on the respective rotator signal.

2. The circuit of claim 1, wherein each of the control logic circuits is configured to provide the respective pulses during the respective time period based on the timer signal and the respective rotator signal.

3. The circuit of claim 2, wherein the timer signal has a triggered state and a reset state, and a respective control logic circuit is configured to start generating the respective pulses when the timer signal transitions to the triggered state and the respective rotator signal is active.

4. The circuit of claim 3, wherein the timer circuit is configured to generate the timer signal based on a comparison of a voltage ramp signal and a timer reference voltage.

5. The circuit of claim 4, wherein the timer signal is transitioned to the triggered state when the voltage ramp signal is greater than the timer reference voltage, and the timer signal is transitioned to the reset state when the voltage ramp signal is less than the timer reference voltage.

6. The circuit of claim 4, wherein the voltage ramp signal is generated based on a voltage control signal indicative of the output voltage and a reset signal.

7. The circuit of claim 6, wherein, when one of the control logic circuits starts generating pulses, the reset signal modifies the voltage ramp signal to transition the timer signal to the reset state.

8. The circuit of claim 7, further comprising a reset signal generation circuit configured to generate the reset signal such that the reset signal is set to a logic high state when any one of the control logic circuits starts generating pulses.

9. The circuit of claim 8, wherein each of the control logic circuit is configured to provide a corresponding pulse generation indication signal to the reset signal generation circuit, wherein the pulse generation indication signal provides an indication that the corresponding control logic circuit has started generating pulses.

10. The circuit of claim 6, further comprising a voltage compensation circuit configured to generate the voltage control signal based on a comparison of a feedback voltage indicative of the output voltage and an output reference voltage.

11. The circuit of claim 1, wherein the rotator circuit is configured to generate the plurality of rotator signals based on the timer signal.

12. A circuit comprising:
a first control logic circuit having a first input, a second input, and an output;
a second control logic circuit having a first input, a second input, and an output;
a timer circuit having an input and an output, the output coupled to the first input of the first control logic circuit and to the first input of the second control logic circuit, and the input of the timer circuit adapted to be coupled to an output terminal; and
a rotator circuit having an input, a first output and a second output, the input coupled to the output of the timer circuit, the first output coupled to the second input of the first control logic circuit and the second output coupled to the second input of the second control logic circuit.

13. The circuit of claim 12, wherein the first control logic circuit is configured to provide a first set of pulses at the corresponding output and the second control logic circuit is configured to provide a second set of pulses at the corresponding output, during different time periods, based on a timer signal at the first input of the first control logic circuit and the second control logic circuit.

14. The circuit of claim 13, further comprising a first current sense comparator circuit coupled to the first control logic circuit and a second current sense comparator circuit coupled to the second control logic circuit, each of the first current sense comparator circuit and the second current sense comparator circuit including a respective peak current comparator circuit configured to generate a respective peak current control signal and a respective valley current comparator circuit configured to generate a respective valley current control signal, based on a respective output current.

15. The circuit of claim 14, wherein the first control logic circuit is configured to provide the first set of pulses further based on the peak current control signal and the valley current control signal from the first current sense comparator circuit and the second control logic circuit is configured to provide the second set of pulses further based on the peak current control signal and the valley current control signal from the second current sense comparator circuit.

16. The circuit of claim 15, wherein the first control logic circuit and the second control logic circuit are configured to generate the first set of pulses and the second set of pulses, respectively, during a PFM mode and wherein the first control logic circuit and the second control logic circuit are configured to generate respective pulse width modulation (PWM) pulses based on the peak current control signal and the valley current control signal during a PWM mode.

17. The circuit of claim 16, wherein, during the PFM mode, the first current sense comparator circuit is enabled only during a time period when the first control logic circuit is generating a pulse, and the second current sense comparator circuit is enabled only during a time period when the second control logic circuit is generating a pulse.

18. A system comprising:
a plurality of power converter circuits, wherein an output terminal of each of the power converter circuits is coupled to a common output terminal;
a plurality of control logic circuits each configured to provide respective pulses to a respective one of the power converter circuits at different time periods;
a timer circuit configured to provide a timer signal to each respective one of the control logic circuits, the timer signal being based on an amplitude of an output voltage at the common output terminal of the power converter circuits, wherein the timer signal determines a frequency of the respective pulses; and
a rotator circuit configured to provide one of a plurality of rotator signals to each respective one of the control logic circuits, wherein each of the rotator signals determines a time period of the different time periods during which the corresponding control logic circuit generates the respective pulses.

19. The system of claim 18, wherein each of the control logic circuits is configured to generate the respective pulses during the respective time period based on the timer signal and the respective rotator signal.

20. The system of claim 19, wherein the timer signal has a triggered state and a reset state, and a respective control logic circuit is configured to start generating the respective pulses when the timer signal transitions to the triggered state and the respective rotator signal is active.
